(19) United States
(12) Patent Application Publication
(10) Pub. No.: US 2019/0377258 A1
(43) Pub. Date: Dec. 12, 2019

(54) IMPRINT PRESSURE ROLLER DEVICE

(71) Applicant: SAMSUNG ELECTRONICS CO., LTD., Suwon-si (KR)

(72) Inventors: Ho YU, Pohang-si (KR); Byeong Sang KIM, Hwaseong-si (KR); Eul-Tae KIM, Suwon-si (KR); Eun Soo HWANG, Seoul (KR)

(21) Appl. No.: 16/205,630

(22) Filed: Nov. 30, 2018

(30) Foreign Application Priority Data
Jun. 11, 2018 (KR) 10-2018-0066807

(51) Int. Cl. G03F 7/00

(52) U.S. Cl. CPC G03F 7/0002

(57) ABSTRACT

An imprint pressure roller device is provided. The imprint pressure roller device includes a roller member that applies pressure downward while rotating about a shaft, a bearing block that is coupled to both ends of the roller member to allow rotation of the roller member and a frame that is coupled to the bearing block to support the roller member and the bearing block, wherein the bearing block includes a coupling portion that is connected to the shaft, a core portion that extends from the coupling portion in a vertical direction, a first coil that completely surrounds sides of the core portion and a second coil that completely surrounds the sides of the core portion and is disposed on the first coil to be spaced apart from the first coil.

### CROSS-REFERENCE TO RELATED APPLICATION

Korean Patent Application No. 10-2018-0066807, filed on Jun. 11, 2018, in the Korean Intellectual Property Office, and entitled: “Imprint Pressure Roller Device,” is incorporated by reference herein in its entirety.

### BACKGROUND

### 1. Field

Embodiments relate to an imprint pressure roller device.

### 2. Description of the Related Art

Nanoimprint lithography has been considered as a technology for forming nanopatterns/nanostructures having various sizes and functions at low cost. Nanoimprint technology may be used like a stamp to simply and cost effectively print nanometer scale patterns using a fine precision mold.

### SUMMARY

Embodiments are directed to an imprint pressure roller device, including a roller member having a shaft, the roller member to apply pressure downward while rotating, opposite ends of the shaft being coupled to a respective bearing block, and a frame coupled to the respective bearing blocks to support the roller member and the bearing blocks. The bearing blocks may include a coupling portion that is connected to the shaft, a core portion that extends from the coupling portion in a vertical direction, a first coil that completely surrounds sides of the core portion, and a second coil that completely surrounds the sides of the core portion and is disposed on the first coil, the second coil being spaced apart from the first coil.

Embodiments are also directed to an imprint pressure roller device, including a chuck to mount a substrate thereon, a roller member having a shaft, opposite ends of the shaft being coupled to a respective bearing block, the roller member to rotate and press an imprint layer and a mold on the substrate while moving in a first direction, the roller member extending in a second direction perpendicular to the first direction, and a frame coupled to the respective bearing blocks to support the roller member and the bearing blocks, and to move the roller member. Each of the bearing blocks may include a coupling portion that is connected to the shaft, a core portion that extends from the coupling portion in a vertical direction, and first and second coils that completely surround sides of the core portion and are spaced apart from each other.

Embodiments are also directed to an imprint pressure roller device, including a chuck on which a substrate is mounted, a roller member having a shaft, the roller member to press an imprint layer and a mold on the substrate while moving in a first direction, the roller member extending in a second direction perpendicular to the first direction, a bearing part coupled opposite ends of the roller member to allow rotation of the roller member, and a frame part coupled to the bearing part to restrict horizontal movement of the roller member while not restricting vertical movement of the roller member.

### BRIEF DESCRIPTION OF THE DRAWINGS

Features will become apparent to those of skill in the art by describing example embodiments with reference to the attached drawings in which:

FIG. 1 illustrates a side view of an imprint pressure roller device according to an example embodiment;

FIG. 2 illustrates a plan view illustrating stripe defects formed on a substrate;

FIG. 3 illustrates a perspective view for explaining the imprint pressure roller device according to an example embodiment;

FIG. 4 illustrates a partial cross-sectional perspective view taken along line A-A′ of FIG. 3;

FIG. 5 illustrates an enlarged perspective view for explaining bearing blocks of FIG. 3;

FIG. 6 illustrates a cross-sectional view for explaining the operation of the bearing blocks of FIG. 3;

FIG. 7 illustrates a cross-sectional view for explaining the operation of the bearing blocks of FIG. 3;

FIG. 8 illustrates a perspective view for explaining an imprint pressure roller device according to an example embodiment;

FIG. 9 illustrates a perspective view for explaining an imprint pressure roller device according to an example embodiment;

FIG. 10 illustrates a cross-sectional view for explaining the operation of bearing blocks of FIG. 9;

FIG. 11 illustrates a cross-sectional view for explaining the operation of the bearing blocks of FIG. 9;

FIG. 12 illustrates a perspective view of an imprint pressure roller device according to an example embodiment;

FIG. 13 illustrates a side view for explaining the imprint pressure roller device of FIG. 12;

FIG. 14 illustrates an enlarged perspective view for explaining the imprint pressure roller device of FIG. 12;

FIG. 15 illustrates an enlarged perspective view for explaining the imprint pressure roller device of FIG. 12;

FIG. 16 illustrates a side view for explaining a coupling wheel and a coupling plate of FIG. 15;

FIG. 17 illustrates a side view of an imprint pressure roller device according to an example embodiment; and

FIG. 18 illustrates a side view of an imprint pressure roller device according to an example embodiment.

### DETAILED DESCRIPTION

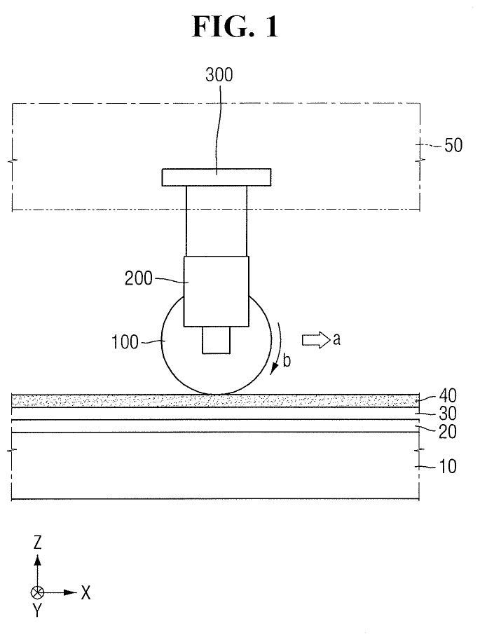

An imprint pressure roller device according to an example embodiment will now be described with reference to FIGS. 1 through 7.

FIG. 1 is a side view of an imprint pressure roller device according to an example embodiment.

Referring to FIG. 1, the imprint pressure roller device according to the present example embodiment includes a chuck 10, a roller member 100, a bearing block 200, and a frame 300.

The chuck 10 may be a support structure on which an object such as a substrate 20 can be mounted. The chuck 10 may have a sufficiently wide upper surface to support the substrate 20 on the upper surface of the chuck 10. The upper surface of the chuck 10 may be flat such that the substrate 20, etc. mounted on the upper surface of the chuck 10 may not be tilted.

Various patterns may formed on the upper surface of the substrate 20. The substrate 20 may be, for example, a glass substrate, a silicon substrate, or a plastic film. The substrate 20 may be a flexible substrate.

An imprint layer 30 may be disposed on the substrate 20. The imprint layer 30 may be a portion where patterns are formed on the substrate 20 by imprinting. The imprint layer 30 may include, for example, a resist layer.

The resist layer may include, for example, a thermoplastic polymer. When heated to a predetermined temperature or higher, the thermoplastic polymer may be plastically deformed. For example, when the thermoplastic polymer is heated to a glass transition temperature or higher, it may be changed from a hard state to a soft state. At this time, if pressure is applied to the thermoplastic polymer in the soft state, plastic deformation may occur.

The thermoplastic polymer may include, for example, polystyrene (PS) or polymethylmethacrylate (PMMA). The thermoplastic material that forms the imprint layer 30 may be formed of various other materials.

In an implementation, the resist layer may include a photocurable resin. The photocurable resin may be cured when irradiated with light such as ultraviolet light. For example, the photocurable resin may be cured by light after patterns are formed by a mold 40.

The imprint layer 30 may be formed to have a large area. For example, the imprint layer 30 may have a diagonal size of 12 inches or more.

The mold 40 may be disposed on the imprint layer 30. The mold 40 may have a flat plate shape, and mold patterns may be formed on a lower surface of the mold 40. The mold 40 may include, for example, silicon, SUS (stainless steel), quartz, etc.

The mold patterns may include, for example, uneven patterns having a periodic shape such as a stripe shape, or patterns of various other shapes.

The imprint layer 30 may be cured using heat or light after being pressed by the mold 40. Nanopatterns may exist on the mold 40 and may be transferred to the imprint layer 30. Accordingly, nanopatterns may be formed on the imprint layer 30.

A first direction X and a second direction Y may be directions intersecting each other. The first direction X and the second direction Y may be, for example, directions orthogonal to each other. The first direction X and the second direction Y may be directions orthogonal to each other from among horizontal directions. A third direction Z may be a direction intersecting both the first direction X and the second direction Y. For example, the third direction Z may be a direction orthogonal to both the first direction X and the second direction Y. The third direction Z may be a vertical direction.

The roller member 100 may extend in the second direction Y. The roller member 100 may be shaped like a cylinder extending in the second direction Y. The roller member 100 may move in one direction, for example, an advancing direction a, while rotating about a shaft that extends in the second direction Y. The roller member 100 may move while rotating about the shaft in a rotation direction b. The advancing direction a and the rotation direction b may be reversed depending on the movement of the roller member 100.

The roller member 100 may press the mold 40 disposed under the roller member 100 against the imprint layer 30 while moving in the advancing direction a. In this pressing process, the nanopatterns located on the mold 40 may be formed on the imprint layer 30.

The bearing block 200 may be coupled to the roller member 100. The bearing block 200 may be coupled to both ends of the roller member 100 in the second direction Y. A pair of two identical bearing blocks 200 may be used.

The bearing blocks 200 may determine the position of the roller member 100 and allow the roller member 100 to freely rotate in the rotation direction b while being moved in the advancing direction a. The bearing blocks 200 may be connected only to the shaft of the roller member 100 and may be separated from a roller portion of the roller member 100 that directly presses the mold 40.

The frame 300 may be coupled to the bearing blocks 200. The frame 300 may be disposed above the bearing blocks 200 and the roller member 100 to control the position of the roller member 100. As the frame 300 moves, the bearing blocks 200 and the roller member 100 connected to the frame 300 may also move simultaneously, and when the frame 300 moves in the advancing direction a, the roller member 100 may also move in the advancing direction a while rotating in the rotation direction b.

The frame 300 may extend in the second direction Y, like the roller member 100, and may be coupled to both of the two bearing blocks 200. Accordingly, the frame 300, the two bearing blocks 200, and the roller member 100 may be fixed to each other.

A guide 50 may support the frame 300. The guide 50 may define a path along which the frame 300 moves. The guide 50 may support the frame 300 while allowing the frame 300 to move, and may be in the form of a slide, rail, or various shapes.

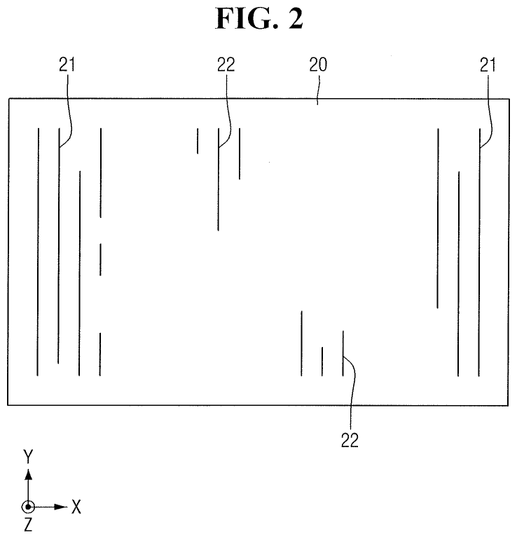

FIG. 2 is a plan view illustrating stripe defects formed on the substrate 20.

Referring to FIGS. 1 and 2, while the roller member 100 is connected to the frame 300 and the bearing blocks 200, it may press the mold 40 only with its own weight. The self-weight of the roller member 100 may be used to apply a uniform pressure to an upper surface of the mold 40. As described in detail herein, the bearing blocks 200 may not contact the roller member 100 in the third direction Z, which may be the direction of force induced by gravity.

The roller member 100 may be moved in the advancing direction a, and when the frame 300 and the bearing blocks 200 move in the advancing direction a, there may be contact in the horizontal direction, i.e., the advancing direction a.

If the roller member 100 is shaken in the first direction X during an imprint process for transferring nano-sized patterns, defects may occur in the imprint layer 30 of the substrate 20. For example, fine voids may be introduced to the imprint layer 30 so as to form full stripe defects 21 or local stripe defects 22. Referring to FIG. 2, the full stripe defects 21 may be stripe defects extending in the second direction Y and formed entirely in the second direction Y of the substrate 20, and the local stripe defects 22 may be stripe defects extending only partly in the second direction Y. If stripe defects such as the full stripe defects 21 and the local stripe defects 22 are formed on the imprint layer 30 with the actual intended positions and shapes of nanopatterns being shaken, the positions and shapes of patterns to be formed on the substrate 20 later may also be different from the intended positions and shapes, which may be detrimental to the performance and reliability of elements formed on the substrate 20.

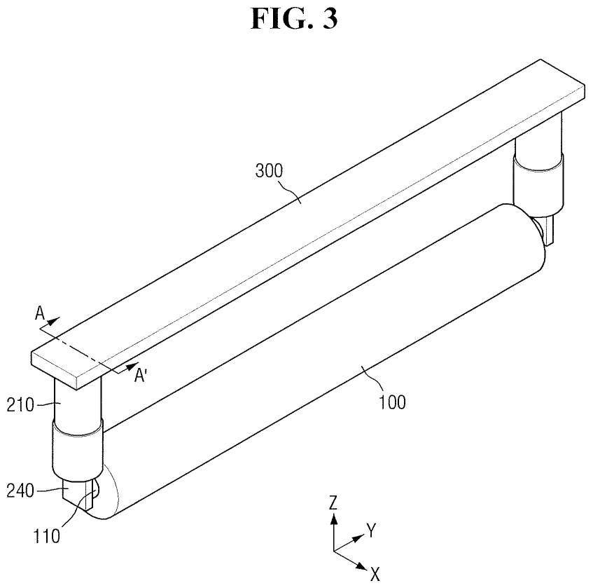

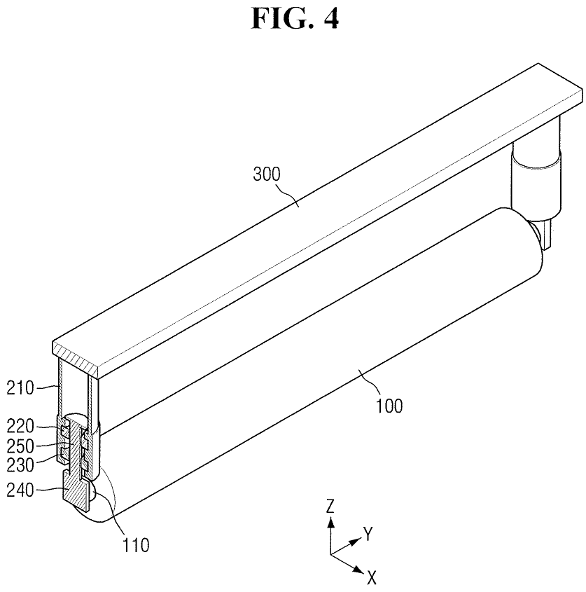

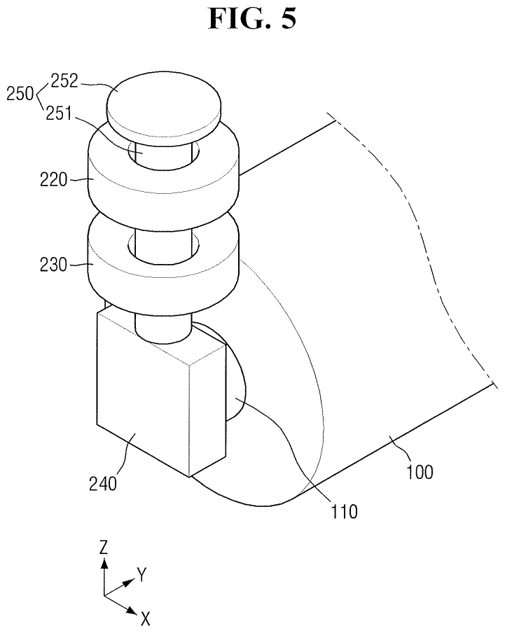

FIG. 3 is a perspective view for explaining the imprint pressure roller device according to an example embodiment. FIG. 4 is a partial cross-sectional perspective view taken along line A-A′ of FIG. 3. FIG. 5 is an enlarged perspective view for explaining the bearing blocks 200 of FIG. 3.

Referring to FIGS. 3 through 5, the roller member 100 may rotate about a shaft 110. The shaft 110 may be directly connected to the bearing blocks 200. The bearing blocks 200 may connect the frame 300 and the roller member 100 in the third direction Z.

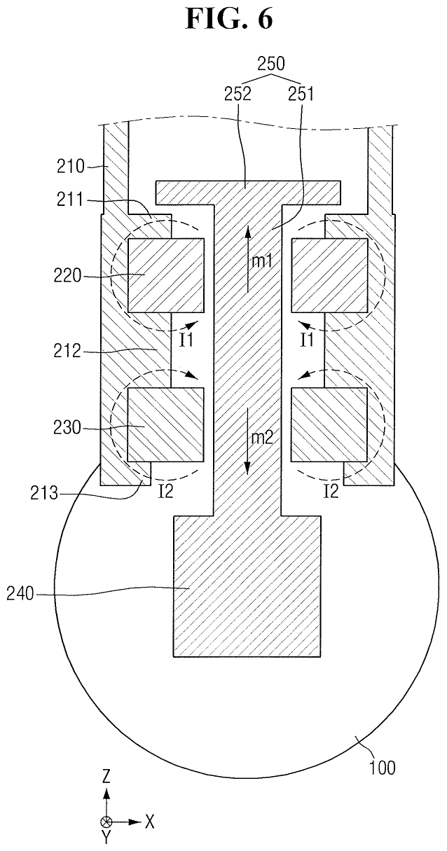

Each of the bearing blocks 200 may include a housing (collectively 210 and 211, 212 and 213 in FIG. 6), a coupling portion 240, a core portion 250, a first coil 220, and a second coil 230.

The housing (210, 211, 212 and 213) may include an outer wall 210, a first protrusion 211, a second protrusion 212 and a third protrusion 213. The outer wall 210 may surround the core portion 250, the first coil 220, and the second coil 230. The outer wall 210 may be a portion directly connected to the frame 300. The outer wall 210 may be coupled and fixed to a lower surface of the frame 300.

The outer wall 210 may protect the core portion 250, the first coil 220, and the second coil 230. In another implementation, the core portion 250, the first coil 220 and the second coil 230 may be exposed without being covered by the outer wall 210.

The first protrusion 211 may protrude inward from the outer wall 210. The first protrusion 211 may cover at least a part of an upper surface of the first coil 220. The first protrusion 211 may include a through-hole through which the core portion 250 can pass. The diameter of the through-hole may be greater than the diameter of a body 251 of the core portion 250 and smaller than the diameter of a head 252 of the core portion 250. When the roller member 100 is not in contact with an underlying surface, the head 252 of the core portion 250 may be supported by an upper surface of the first protrusion 211 so that the frame 300 and the bearing blocks 200 remain coupled to each other.

The second protrusion 212 may protrude inward from the outer wall 210. The second protrusion 212 may be located under the first protrusion 211. The second protrusion 212 may cover at least a part of a lower surface of the first coil 220 and at least a part of an upper surface of the second coil 230. The first coil 220 may be positioned between the first protrusion 211 and the second protrusion 212.

The second protrusion 212 may include a through-hole through which the core portion 250 can pass. The second protrusion 212 under the first coil 220 may support the first coil 220.

The third protrusion 213 may protrude inward from the outer wall 210. The third protrusion 213 may be located under the first protrusion 211 and the second protrusion 212. The third protrusion 213 may cover at least a part of a lower surface of the second coil 230. The second coil 230 may be positioned between the second protrusion 212 and the third protrusion 213.

The third protrusion 213 may include a through-hole through which the core portion 250 can pass. The third protrusion 213 under the second coil 230 may support the second coil 230.

The coupling portion 240 may be directly connected to the shaft 110. The coupling portion 240 may form a lower end of the core portion 250. The shaft 110 may extend in the second direction Y, the core portion 250 may extend in the third direction Z, and the shaft 110 and the core portion 250 may be connected to each other in the coupling portion 240.

The core portion 250 may extend from the coupling portion 240 in the third direction Z. The core portion 250 may be wholly or partially formed of a material influenced by a magnetic field generated by the first coil 220 and the second coil 230, e.g., a magnetic material, etc. Accordingly, magnetic forces may be applied to the core portion 250 by currents flowing through the first coil 220 and the second coil 230.

The core portion 250 may include the body 251 and the head 252. The body 251 of the core portion 250 may be a portion surrounded by the first coil 220 and the second coil 230. The body 251 may extend in the third direction Z from the coupling portion 240. The body 251 may pass through the through-holes defined by the first protrusion 211, the second protrusion 212 and the third protrusion 213.

The head 252 may be formed at an end of the core portion 250. The head 252 may be connected to the body 251 in the third direction Z. The body 251 of the core portion 250 may be positioned between the head 252 of the core portion 250 and the coupling portion 240.

The head 252 may have a larger cross-sectional area than the body 251 in a horizontal plane. Accordingly, the head 252 may be unable to pass through the through-hole defined by the first protrusion 211. The head 252 may be disposed on the first protrusion 211.

The first coil 220 may completely surround sides of the body 251 of the core portion 250. The first coil 220 may be formed by winding a conducting wire in the third direction Z. The first coil 220 may surround all sides of the body 251. The first coil 220 may be covered by the outer wall 210 and supported by the second protrusion 212.

The second coil 230 may completely surround the sides of the body 251 of the core portion 250. The second coil 230 may be formed by winding a conducting wire in the third direction Z, like the first coil 220. The second coil 230 may surround all sides of the body 251. The second coil 230 may be located below the first coil 220. The second coil 230 may be spaced apart from the first coil 220 in the third direction Z. The second protrusion 212 may be positioned between the first coil 220 and the second coil 230. The second coil 230 may be covered by the outer wall 210 and supported by the third protrusion 213.

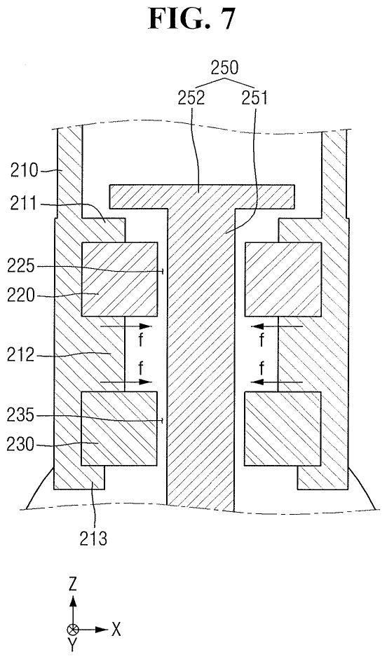

FIGS. 6 and 7 are cross-sectional views showing vertical and lateral forces generated by the first coil 220 and the second coil 230.

FIG. 6 is a cross-sectional view for explaining the operation of the bearing blocks 200 of FIG. 3.

Referring to FIG. 6, a first current I1 may flow through the first coil 220. The direction of the first current I1 may be a downward direction around an outer surface of the first coil 220, as illustrated in FIG. 6. The body 251 may be formed of a material that interacts with a magnetic field generated by the first current I1 flowing in the first coil 220 such that a first magnetic force m1 is generated in the body 251 located inside the first coil 220.

A second current I2 may flow through the second coil 230. The direction of the second current I2 may be an upward direction around an outer surface of the second coil 230, as illustrated in FIG. 6. The body 251 may be formed of a material that interacts with a magnetic field generated by the second current I2 flowing in the second coil 230 such that a second magnetic force m2 is generated in the body 251 located inside the second coil 230.

In an example embodiment, the magnitude of the first magnetic force m1 and the magnitude of the second magnetic force m2 may be equal to each other, and the direction of the first magnetic force m1 and the direction of the second magnetic force m2 may be opposite to each other. Accordingly, the sum, e.g., in the third direction Z, of the magnetic forces m1 and m2 formed by operation of the first coil 220 and the second coil 230 may be zero such that the core portion 250 receives no net additional force in the third direction Z, for example, in the direction of gravity. Thus, the roller member 100 may not receive a net force in the third direction Z from the bearing blocks 200, and may press the mold 40 only with its own weight during the imprint process.

FIG. 7 is a cross-sectional view for explaining the operation of the bearing blocks 200 of FIG. 3.

Referring to FIGS. 6 and 7, the first current I1 flowing in the first coil 220 may form an external force f acting on the body 251 in the direction of the body 251. The external force f may be uniformly applied to all sides of the body 251. The body 251 may be fixed in a lateral direction, for example, the X direction, within the first coil 220 by the external forces f acting thereon as a result of the first current I1 flowing in the first coil 220.

Similarly, the second current flowing in the second coil 230 may form an external force f in the direction of the body 251 of the core portion 250, and the external force f may be uniformly applied to all sides of the body 251 such that the body 251 may be fixed in a lateral direction, for example, the X direction, as a result of the second current I2 flowing in the second coil 230.

As illustrated in FIG. 6, the first and second coils 220 and 230 may apply forces to the body 251 in the third direction Z and, when these forces are canceled out, the net force applied in the Z direction to the body 251 of the core portion 250 may be zero.

The external forces f generated by the magnetic fields may be applied to the body 251 in a non-contact manner. Referring to FIG. 7, the first coil 220 and the body 251 of the core portion 250 may not contact each other due to a first gap 225, and the second coil 230 and the body 251 of the core portion 250 may not contact each other due to a second gap 235.

The imprint pressure roller device according to the present example embodiment may help reduce or eliminate shaking of the roller member 100 in the horizontal direction while not fixing the roller member 100 in the vertical direction so that the roller member 100 presses the mold 40 only with its own weight. The first magnetic force m1 and the second magnetic force m2 respectively generated by the first coil 220 and the second coil 230 may be net opposites in a vertical direction, and the roller member 100 may not be fixed in the vertical direction, whereas the core portion 250 of each bearing block 200 may be fixed in the horizontal direction by the external forces f generated by the first coil 220 and the second coil 230, thus causing the roller member 100 to be fixed in the horizontal direction.

The imprint pressure roller device according to the present example embodiment may improve the reliability of the imprint process, for example, by reducing or preventing the formation of the full stripe defects 21 or the local stripe defects 22 of FIG. 2.

An imprint pressure roller device according to an example embodiment will now be described with reference to FIGS. 1, 7 and 8. A redundant description of elements and features identical to those of the above-described embodiments will be given briefly or omitted.

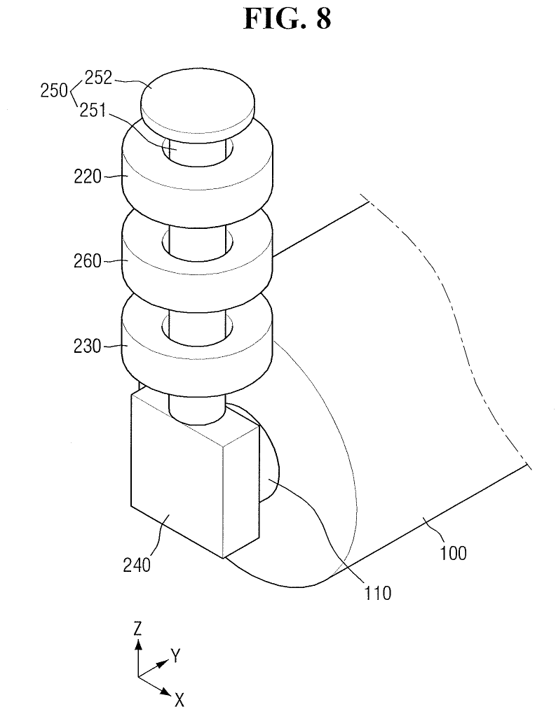

FIG. 8 is a perspective view for explaining an imprint pressure roller device according to an example embodiment.

Referring to FIGS. 1, 7, and 8, each bearing block 200 of the imprint pressure roller device according to the embodiments may include three coils.

For example, each bearing block 200 may include a first coil 220, a second coil 230, and a third coil 260.

The third coil 260 may be positioned between the first coil 220 and the second coil 230. The third coil 260 may completely surround sides of a body 251 of a core portion 250. The third coil 260 may be formed by winding a conducting wire in the third direction Z. The third coil 260 may surround all sides of the body 251.

A third current may flow through the third coil 260. The third current may have the same direction as the first current I1 of FIG. 6 or may have the same direction as the second current I2 of FIG. 6. When the third current of the third coil 260 is formed in the same direction as the first current I1, a third magnetic force formed in the third direction Z by the third coil 260 may act in the upward direction, like the first magnetic force m1. Conversely, when the third current of the third coil 260 is formed in the same direction as the second current I2, the third magnetic force formed in the third direction Z by the third coil 260 may act in the downward direction, like the second magnetic force m2.

In an implementation, the third magnetic force may be in the same direction as the first magnetic force m1, and the sum of the magnitude of the first magnetic force m1 and the magnitude of the third magnetic force may be the same as the second magnetic force m2, while the directions of the first magnetic force m1 and the third magnetic force may be opposite to the direction of the second magnetic force m2 such that the first magnetic force m1 and the third magnetic force cancel out the second magnetic force m2. Thus, the final resultant force may be zero in the vertical direction.

In another implementation, the third magnetic force may be in the same direction as the second magnetic force m2, and the sum of the magnitude of the second magnetic force m2 and the magnitude of the third magnetic force may be the same as the first magnetic force m1, while the directions of the second magnetic force m2 and the third magnetic force may be opposite to the direction of the first magnetic force m1 such that the second magnetic force m2 and the third magnetic force cancel out the first magnetic force m1. Thus, the final resultant force may be zero in the vertical direction.

Thus, the three coils may not apply a net external force in the vertical direction, and the roller member 100 may press the mold 40 only with its own weight. Further, the core portion 250 can be fixed by the first coil 220, the second coil 230 and the third coil 260, which may help reduce or prevent stripe defects due to shaking.

In other implementations, the number of coils may be, for example, four or more, and the magnitudes of currents, the density of coils, etc., may be adjusted so that an external force in the vertical direction is zero.

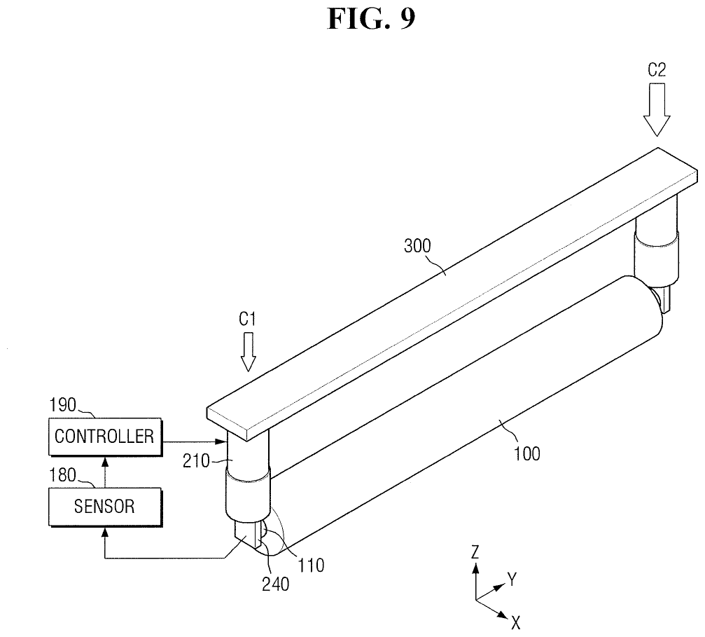

An imprint pressure roller device according to an example embodiment will now be described with reference to FIGS. 9 through 11. A redundant description of elements and features identical to those of the above-described embodiments will be given briefly or omitted.

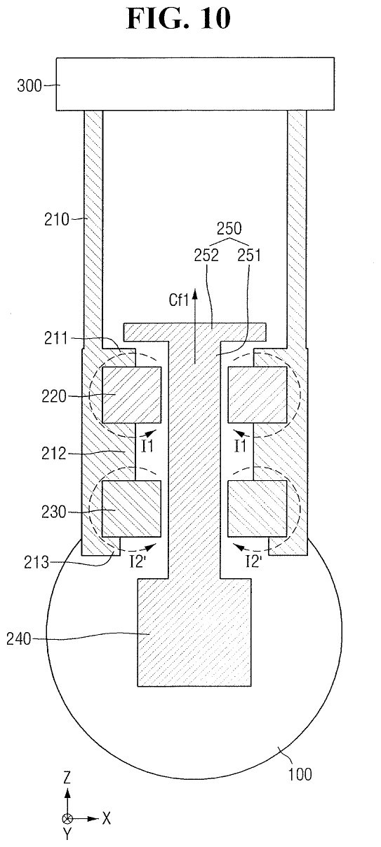

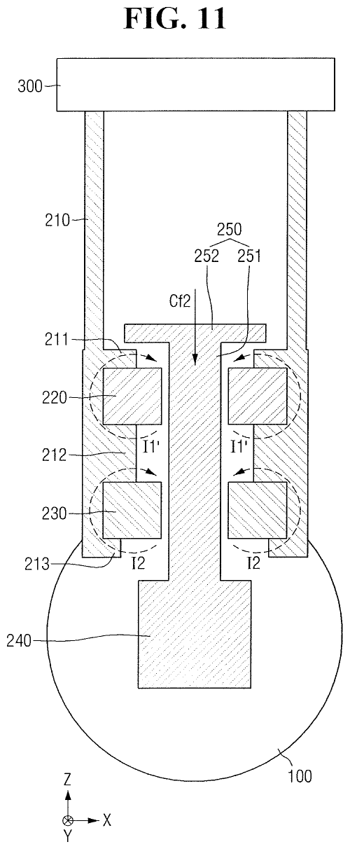

FIG. 9 is a perspective view for explaining an imprint pressure roller device according to an example embodiment. FIG. 10 is a cross-sectional view for explaining the operation of bearing blocks 200 of FIG. 9. FIG. 11 is a cross-sectional view for explaining the operation of the bearing blocks 200 of FIG. 9.

Referring to FIGS. 9 through 11, the imprint pressure roller device according to the present example embodiment may include a sensor 180 and a controller 190.

The sensor 180 may sense pressure applied to a mold 40 by the roller member 100. For example, the sensor 180 may detect a case where a first resultant force C1 and a second resultant force C2 applied to the positions of the two bearing blocks 200 located at both ends of the roller member 100 are not the same.

Here, each of the first resultant force C1 and the second resultant force C2 may refer to a force obtained by combining a force due to the self-weight of the roller member 100 and forces due to other factors.

The controller 190 may receive pressure information sensed by the sensor 180 from the sensor 180. The controller 190 may apply currents to the two bearing blocks 200 located at both ends of the roller member 100 so that the first and second resultant forces C1 and C2 become equal.

For example, referring to FIGS. 9 and 10, the controller 190 may apply a first current I1 to a first coil 220 and a (2-1)^{th} current I2′ to a second coil 230. The (2-1)^{th} current I2′ may be in the same direction as the first current I1, and magnetic forces generated by the first coil 220 and the second coil 230 may be in the same direction. Therefore, the two magnetic forces may be combined to form a first vertical magnetic force Cf1 in the upward direction, as shown in FIG. 10.

Conversely, referring to FIGS. 9 and 11, the controller 190 may apply a (1-1)^{th} current I1′ to the first coil 220 and a second current I2 to the second coil 230. The (1-1)^{th} current I1′ may be in the same direction as the second current I2, and magnetic forces generated by the first coil 220 and the second coil 230 may be in the same direction. Therefore, the two magnetic forces may be combined to form a second vertical magnetic force Cf2 in the downward direction.

The imprint pressure roller device may maintain a uniform pressure along the second direction Y. Changes in the pressure under the roller member 100 such that the pressure is not uniform may arise due to various reasons, for example, the non-uniform thickness of the roller member 100 an inclined upper surface of a chuck 10, etc.

The imprint pressure roller device according to the present example embodiment may sense the pressure under the roller member 100 using the sensor 180 and correct the pressure using the controller 190. For example, the controller 190 may adjust the directions and magnitudes of currents applied to the coils of the bearing blocks 200 at both ends of the roller member 100 so that the first and second resultant forces C1 and C2 become equal to each other.

The controller 190 may selectively use the first vertical magnetic force Cf1 acting in the upward direction as illustrated in FIG. 10 or use the second vertical magnetic force Cf2 acting in the downward direction as illustrated in FIG. 11. In addition, the controller 190 may finely adjust the magnitude of the first vertical magnetic force Cf1 and the magnitude of the second vertical magnetic force Cf2 by adjusting the magnitudes of currents.

Accordingly, the imprint pressure roller device according to the present example embodiment may apply a uniform pressure to under the roller member 100 through the subsequent correction of the controller 190, which may improve the reliability of the imprint process.

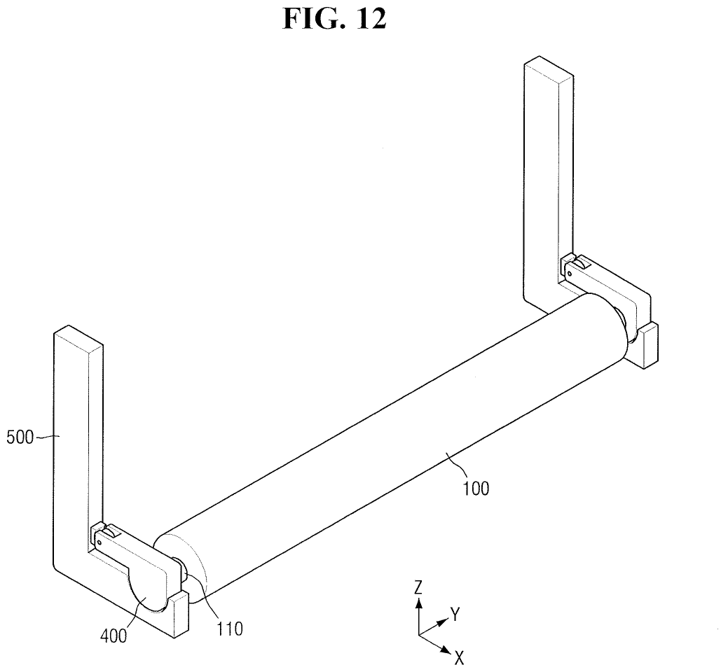

An imprint pressure roller device according to an example embodiment will now be described with reference to FIGS. 12 through 16. A redundant description of elements and features identical to those of the above-described embodiments will be given briefly or omitted.

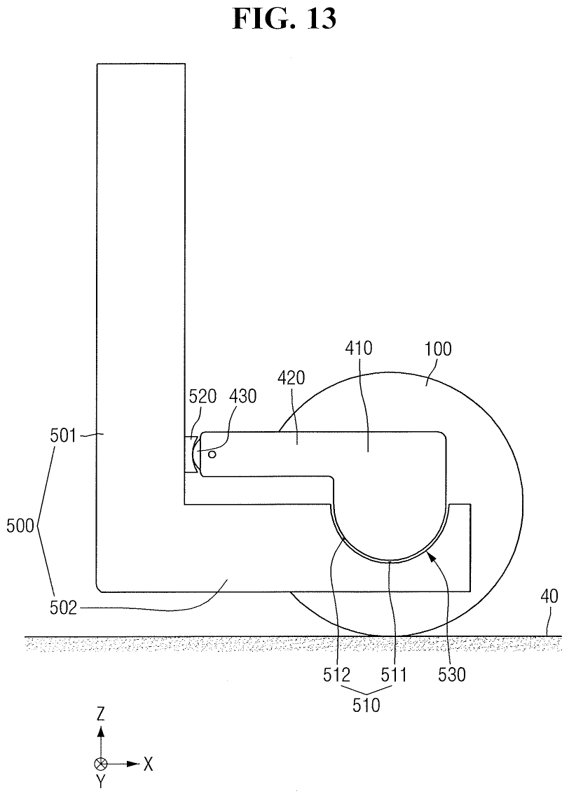

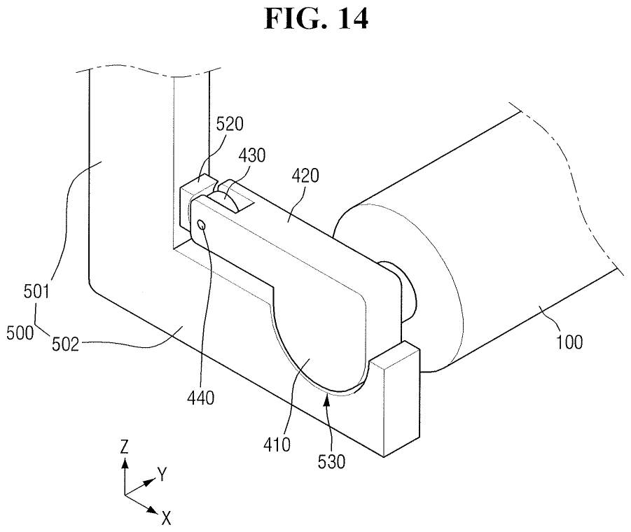

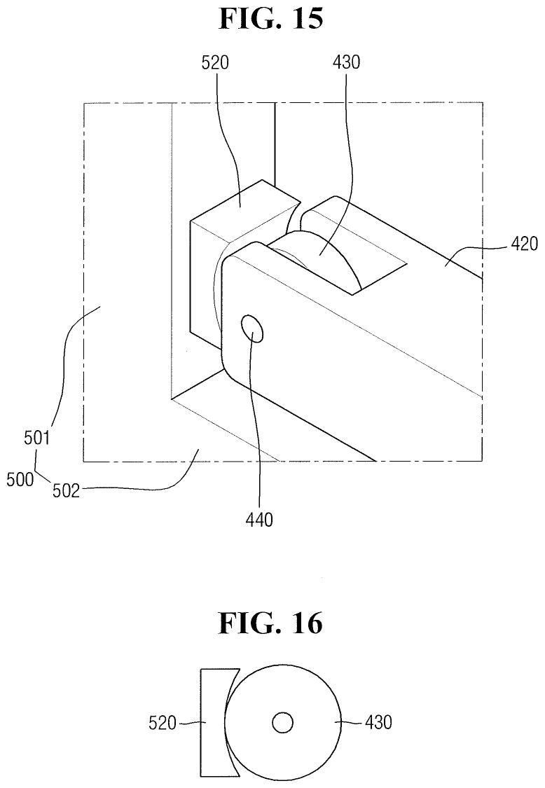

FIG. 12 is a perspective view of an imprint pressure roller device according to an example embodiment. FIG. 13 is a side view for explaining the imprint pressure roller device of FIG. 12. FIG. 14 is an enlarged perspective view for explaining the imprint pressure roller device of FIG. 12. FIG. 15 is an enlarged perspective view for explaining the imprint pressure roller device of FIG. 12. FIG. 16 is a side view for explaining a coupling wheel 430 and a coupling plate 520 of FIG. 15.

Referring to FIGS. 12 through 16, the imprint pressure roller device according to the present example embodiment may include the roller member 100, hook units 500, and bearing parts 400.

The roller member 100 may extend in the second direction Y. The roller member 100 and the bearing parts 400 may be mounted on the hook units 500. Upper ends of the hook units 500 may be connected to the frame 300 of FIG. 1. Accordingly, as the frame 300 moves, the hook units 500 may also move.

Each of the hook units 500 may include a first supporting arm 501 and a second supporting arm 502. The first supporting arm 501 may be a portion directly connected to the frame 300 of FIG. 1. The first supporting arm 501 may extend in the third direction Z. In an implementation, the imprint pressure roller device may also include the first supporting arm 501 extending in a direction not completely parallel to the third direction Z. The second supporting arm 502 may extend from the first supporting arm 501 in the horizontal direction, that is, in the first direction X. The direction in which the second supporting arm 502 extends may also not be completely parallel to the first direction X.

The first supporting arm 501 may include a concave portion 530. The concave portion 530 may be a portion with which a convex portion 410 of each bearing part 400 is engaged. When the roller member 100 is not positioned on a mold 40, each bearing part 400 may be mounted on the concave portion 530. Thus, the concave portion 530 may support the roller member 100. The concave portion 530 may not contact each bearing part 400 when the roller member 100 is set on the mold 40.

The second supporting arm 502 may include the coupling plate 520. The coupling plate 520 may be coupled to the coupling wheel 430 of each bearing part 400.

In an implementation, the coupling plate 520 or the coupling wheel 430 may be a magnetic body, and the coupling plate 520 and the coupling wheel 430 may be magnetically attracted to each other.

Each of the bearing parts 400 may include the convex portion 410, an extending portion 420, and the coupling wheel 430. The convex portion 410 may be directly connected to a shaft 110. The convex portion 410 may be a portion mounted on the concave portion 530 of the second supporting arm 502.

The convex portion 410 may not contact the concave portion 530 when the roller member 100 is set on the mold 40. For example, referring to FIG. 13, the concave portion 530 and the convex portion 410 may be separated from each other by a third gap 510 including gap segments 511 and 512. The concave portion 530 and the convex portion 410 may be vertically spaced apart from each other by vertical gap 511, and the roller member 100 may press the mold 40 with the uniform pressure when pressing the mold 40 with its own weight.

The extending portion 420 may extend from the convex portion 410 toward the first supporting arm 501. The extending portion 420 may extend in the horizontal direction, that is, in the first direction X, and a groove in which the coupling wheel 430 is to be placed may be formed at an end of the extending portion 420.

The coupling wheel 430 may be fixed to the extending portion 420 by a coupling pin 440. The coupling wheel 430 may be freely rotatable about the coupling pin 440. Likewise, when the coupling wheel 430 is coupled and fixed to the coupling plate 520, each bearing part 400, that is, the extending portion 420 and the convex portion 410 may be rotatable about the coupling pin 440. Considering the moving range of the roller member 100, each bearing part 400 may be limited in movement in the horizontal direction while being allowed to move in the vertical direction.

In an implementation, at least one of the coupling wheel 430 and the coupling plate 520 may be a magnetic body, and the coupling wheel 430 and the coupling plate 520 may be magnetically attracted to each other.

A horizontal gap 512 may be maintained between the concave portion 530 and the convex portion 410 by the extending portion 420 and the coupling wheel 430 such that the concave portion 530 and the convex portion 410 do not contact each other in the horizontal direction.

Referring to FIG. 16, the coupling wheel 430 may have a circular profile when viewed from a side in the second direction Y. The coupling plate 520 coupled to the coupling wheel 430 may have a concave surface.

The concave surface of the coupling plate 520 may be designed to make up for the point contact between the coupling wheel 430 and the coupling plate 520. Thus, the coupling plate 520 and the coupling wheel 430 may contact each other at a different point each time, and the surface of the coupling plate 520 may be made to have a concave curvature so that the coupling plate 520 and the coupling wheel 430 make point contact with each other at the same position whenever they are coupled to each other.

The imprint pressure roller device according to the present example embodiment may keep the roller member 100 not in contact with the hook units 500 in the vertical direction, so that the roller member 100 can apply pressure only with its own weight. At the same time, the imprint pressure roller device according to the present example embodiment may prevent shaking in the horizontal direction when moving in the advancing direction a of FIG. 1 by coupling the coupling wheel 430 and the coupling plate 520 in the horizontal direction using a magnetic body.

In addition, in the imprint pressure roller device according to the present example embodiment, the coupling wheel 430 may be fixed to the extending portion 420 by the coupling pin 440 while being freely rotatable, and no force may be applied to the roller member 100 in the vertical direction.

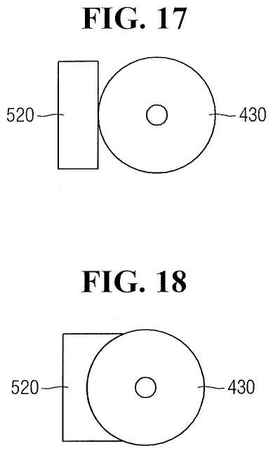

An imprint pressure roller device according to an example embodiment will now be described with reference to FIG. 17. A redundant description of elements and features identical to those of the above-described embodiments will be given briefly or omitted.

FIG. 17 is a side view of an imprint pressure roller device according to an example embodiment.

Referring to FIG. 17, in the imprint pressure roller device according to the present example embodiment, a coupling plate 520 may have a flat surface.

When the surface of the coupling plate 520 is flat, the distance between a roller member 100 and a first supporting arm 501 may not be changed according to the contact position with a coupling wheel 430. Accordingly, the horizontal position of the roller member 100 may always be the same. This may make the dispersion of the imprint process uniform so that the same elements can be manufactured in each process and may improve the reliability of the process.

An imprint pressure roller device according to an example embodiment will now be described with reference to FIG. 18. A redundant description of elements and features identical to those of the above-described embodiments will be given briefly or omitted.

FIG. 18 is a side view of an imprint pressure roller device according to an example embodiment.

Referring to FIG. 18, in the imprint pressure roller device according to the present example embodiment, a surface of a coupling plate 520 may be a concave curved surface completely corresponding to a curved surface of a coupling wheel 430.

When the surface of the coupling plate 520 is a concave curved surface completely corresponding to the curved surface of the coupling wheel 430, the coupling wheel 430 and the coupling plate 520 may make surface contact, not point contact, with each other. Accordingly, a coupling surface of the coupling wheel 430 and the coupling plate 520 may always be at the same position.

When the coupling point is always the same in each process, the vertical and horizontal positions of each bearing part 400 may always be maintained the same. This may make the dispersion of the imprint process uniform so that the same elements can be manufactured in each process and may improve the reliability of the process.

By way of summation and review, nanoimprint lithography may be used to apply an imprint resin onto a layer on which patterns are to be formed, followed by pressing and imprinting the imprint resin with a stamp designed in a desired pattern, and patterning a predetermined layer by dry or wet etching.

In order to perform imprinting, a pressure roller may be placed on a stamp, for example, a mold, and moved in one direction to form patterns. If the pressure roller presses the upper surface of the substrate with a non-uniform pressure, patterns formed on the upper surface of the substrate may also be non-uniform.

As described above, embodiments may provide an imprint pressure roller device that performs an imprint process with a uniform pressure.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An imprint pressure roller device, comprising:
a roller member having a shaft, the roller member to apply pressure downward while rotating, opposite ends of the shaft being coupled to a respective bearing block; and
a frame coupled to the respective bearing blocks to support the roller member and the bearing blocks,
wherein each of the bearing blocks include:
a coupling portion that is connected to the shaft;
a core portion that extends from the coupling portion in a vertical direction;
a first coil that completely surrounds sides of the core portion; and
a second coil that completely surrounds the sides of the core portion and is disposed on the first coil, the second coil being spaced apart from the first coil.

2. The roller device as claimed in claim 1, wherein the first and second coils are not in contact with the core portion.

3. The roller device as claimed in claim 1, wherein the first coil forms a first magnetic field of a first direction in response to a first current, and the second coil forms a second magnetic field of a second direction in response to a second current, wherein the first and second directions are vertical directions.

4. The roller device as claimed in claim 3, wherein the first and second directions are opposite directions.

5. The roller device as claimed in claim 3, wherein magnitudes of the first and second magnetic fields are the same.

6. The roller device as claimed in claim 1, wherein the bearing block includes a housing that supports the core portion and the first and second coils.

7. The roller device as claimed in claim 6, wherein the housing includes:
an outer wall that covers the core portion and the first and second coils;
a protrusion that protrudes inward from the outer wall; and
a through-hole in the protrusion, the core portion passing through the through-hole.

8. The roller device as claimed in claim 7, wherein the core portion includes:
a body that passes through the through-hole and is surrounded by the first and second coils; and
a head that extends from the body, has a diameter greater than that of the through-hole, and is located on the protrusion.

9. The roller device as claimed in claim 1, further comprising:
a sensor that senses pressure under the roller member; and
a controller that changes the pressure under the roller member by adjusting polarities and magnitudes of currents applied to the first and second coils.

10. An imprint pressure roller device, comprising:
a chuck to mount a substrate thereon;
a roller member having a shaft, opposite ends of the shaft being coupled to a respective bearing block, the roller member to rotate and press an imprint layer and a mold on the substrate while moving in a first direction, the roller member extending in a second direction perpendicular to the first direction; and
a frame coupled to the bearing blocks to support the roller member and the respective bearing blocks, and to move the roller member,
wherein each of the bearing blocks include:
a coupling portion that is connected to the shaft;
a core portion that extends from the coupling portion in a vertical direction; and
first and second coils that completely surround sides of the core portion and are spaced apart from each other.

11. The roller device as claimed in claim 10, wherein the mold includes nanopatterns.

12. The roller device as claimed in claim 10, wherein the bearing block allows the roller member to press the mold only with self-weight of the roller member.

13. The roller device as claimed in claim 10, wherein the first and second coils form magnetic fields of different directions.

14. The roller device as claimed in claim 10, wherein the core portion is not in contact with the first and second coils.

15. An imprint pressure roller device, comprising:
a chuck on which a substrate is mounted;
a roller member having a shaft, the roller member to press an imprint layer and a mold on the substrate while moving in a first direction, the roller member extending in a second direction perpendicular to the first direction;
a bearing part coupled opposite ends of the roller member to allow rotation of the roller member; and
a frame part coupled to the bearing part to restrict horizontal movement of the roller member while not restricting vertical movement of the roller member.

16. The roller device as claimed in claim 15, wherein the bearing part includes:
a convex portion;
an extending portion that extends from the convex portion; and
a coupling wheel that is rotatably fixed to an end of the extending portion.

17. The roller device as claimed in claim 16, wherein the frame part includes:
a frame; and
a hook unit that is connected to the frame and directly coupled to the bearing part,
wherein the hook unit includes:
a concave portion on which the convex portion is mounted vertically and
a coupling plate that is horizontally coupled to the coupling wheel by magnetism.

18. The roller device as claimed in claim 17, wherein the concave portion and the convex portion are horizontally spaced apart from each other by a gap.

19. The roller device as claimed in claim 17, wherein the coupling plate has a concave surface.

20. The roller device as claimed in claim 19, wherein the bearing part includes:
a core portion that is connected to the shaft of the roller member; and
first and second coils that surround the core portion while not contacting the core portion.
